(19) United States
(12) Patent Application Publication
(10) Pub. No.: US 2015/0377992 A1
(43) Pub. Date: Dec. 31, 2015

(54) Generation of Magnetic Fields for MRI with Loops Having Current Shunts

(71) Applicant: Hardave S. KHARBANDA, San Antonio, TX (US)

(72) Inventor: Hardave S. KHARBANDA, San Antonio, TX (US)

(21) Appl. No.: 14/768,215

(22) PCT Filed: Feb. 14, 2013
(86) PCT No.: PCT/US2013/026006

§ 371 Date: Aug. 14, 2015

(51) Int. Cl. G01R 33/3875; G01R 33/381; G01R 33/385

(52) U.S. Cl. CPC G01R 33/3875; G01R 33/385; G01R 33/381

(57) ABSTRACT

A conducting loop has thick cross section and is powered by a single voltage source capable of producing extremely high currents. Anti-parallel segments of the loop are brought in close proximity to each other and the unpaired segments in this loop are shaped to collectively form a homogenous B₀ field. Voltage sources shunt current from one point of the thick loop to another such that the resulting redistribution of current within the thick loop allows it to simultaneously establish required gradient fields and/or shimming fields in addition to its Bo field.

### CROSS REFERENCE TO RELATED APPLICATION

This application is related to International Application No. PCT/U.S. 2012/050462, which was filed on Aug. 10, 2012 and which had claimed the benefit of U.S. Provisional Patent Application No. 61/574,823 filed on Aug. 10, 2011.

### STATEMENT REGARDING FEDERALLY FUNDED RESEARCH AND DEVELOPMENT

This disclosure was not the subject of federally sponsored research or development.

### TECHNICAL FIELD

The present disclosure pertains to the establishment of magnetic field patterns through the application of electrical currents; more particularly, the present disclosure pertains to the establishment of magnetic field patterns in the context of Magnetic Resonance Imaging (MRI) scanners and in the context of other systems such as Nuclear Magnetic Resonance Spectroscopy, Electron Paramagnetic Resonance Imaging, and Electron Paramagnetic Resonance Spectroscopy that also require establishment of precise magnetic field patterns for the elicitation of information from a subject.

### BACKGROUND ART

A Magnetic Resonance Imaging (MRI) scanner and other similar devices are systems that establish magnetic fields so as to precisely manipulate the orientations of magnetic moments inherently present within a subject. This manipulation causes the magnetic moments to generate electrical signals within the scanner, and these signals are in turn used to construct detailed images of the internal composition of the subject.

The magnetic field seen within an MRI scanner during imaging is normally the sum of two or more very different magnetic field patterns produced by the scanner. These patterns must be carefully designed and timed so that their net effect produces the magnetic moment orientations desired at a particular instant of time within the volume of the scanner specifically designated for imaging. The magnetic field patterns considered critical to MR image acquisition are the Bₒ field, which is very strong and homogenous; the B₁ field, which fluctuates at a radio frequency; and the x-gradient field, y-gradient field, and z-gradient field, the magnitude of each of which changes approximately linearly in the x-, y-, and z-directions, respectively. Shimming magnetic fields are very often also used, for improvement of the homogeneity of the B₀ field.

Each of the above magnetic field patterns is normally produced by a distinct structure within the scanner, and each such structure is either a configuration of electrical currents or a configuration of permanent magnets. In the case of resistive MRI scanners, all of the magnetic field patterns are produced by non-superconducting electrical structures.

MRI imaging has been applied with great success to disease diagnosis. However, the extension of MRI to disease screening, including cancer screening, has unfortunately been relatively limited. Two factors significantly limiting the use of MRI for screening are the relatively high cost generally associated with scanner construction and the discomfort associated with the typically small patient space found within MRI scanners.

One approach to making scanners more inexpensive and spacious, and to therefore develop a scanner specifically oriented towards disease screening, would be to simultaneously generate a plurality of the magnetic field patterns used in MRI with a configuration carrying the sum of their respective electrical currents. It is in principle conceivable to sum the currents of the B₀ field, gradient fields, and shimming fields because the vectors of all of these fields happen to be principally oriented in a single direction, by convention the z-direction.

However, while methods have been developed that appear to be very successful in producing a plurality of gradient fields and/or shimming fields with a summed current configuration, no practical means has yet been introduced to specifically combine the B₀ field with gradient fields and/or shimming fields. For example, U.S. Pat. No. 6,492,817 to Gebhardt et al. shows an electrical configuration that can simultaneously establish different magnetic field patterns and that consists of a series of parallel concentric loops connected by regularly spaced line segments oriented perpendicularly to the plane of the loops. Because the currents required for a B₀ field are on the order of tens of thousands of Amps when loop winding is not used, each loop in this structure contributing to a hypothetical B₀ field would have to have a voltage source capable of delivering extremely large currents. Assuming a minimum of four loops for a sufficiently homogenous B₀ field, four voltage sources for extremely large currents would therefore be needed for that structure to produce a B₀ field among its other magnetic field patterns.

U.S. Pat. No. 6,933,724 to Watkins et al. has disclosed an electrical configuration within which individual loops have been replaced with separate loop segments or arcs with independent voltage sources. The current pattern in each segmented loop, and in the structure as a whole, is clearly able to represent a sum of current patterns associated with different MRI magnetic field patterns. However, here every segment used to contribute to a hypothetical B₀ field would require a voltage source able to generate tens of thousands of Amps. Again assuming the assembly of a minimum of four loops for a B₀ field, and further assuming that each segmented loop of the Watkins et al. structure consists of at least four segments, sixteen sources of extremely high current would be needed if this structure simultaneously produced a Bₒ field along with its other magnetic field patterns. Beyond that very impractical requirement, the extremely high return current associated with each segment contributing to a B₀ field would lead to a wasting of energy and would additionally be likely to significantly distort the magnetic field within the imaging volume of the scanner.

### DISCLOSURE

It is an object of this disclosure to provide a structure able to establish a B₀ field along with one or more other magnetic field patterns via a summed current configuration, without requiring a plurality of voltage sources of extremely high current or having to deal with the other problems mentioned above.

This object is achieved in accordance with the present disclosure through an embodiment involving a conducting loop with thick cross section and a single voltage source capable of producing extremely high currents. Antiparallel segments of the loop are brought in close proximity to each other, meaning that the loop is effectively “pinched” at one or more locations, and each pair of antiparallel segments contributes approximately zero magnetic field within the imaging volume of the scanner. The unpaired segments in this loop are shaped to collectively form a homogenous B₀ field. Voltage sources then shunt current from one point of the thick loop to another such that the resulting redistribution of current within the thick loop causes it to simultaneously establish required gradient fields and/or shimming fields in addition to its B₀ field.

### BRIEF DESCRIPTION OF DRAWINGS

A still better understanding of the disclosed system and method for the simultaneous establishment of a B₀ field and other magnetic field patterns with a single thick loop may be had by reference to the drawing figures wherein:

FIG. 1 is a schematic circuit diagram showing a single thick loop as a thick line, with attached current shunts, capable of producing a B₀ field, x-gradient field, y-gradient field, and z-gradient field.

FIG. 2 is a schematic circuit diagram showing actual currents that might be associated with any one of the circular structures within the single thick loop of FIG. 1.

FIG. 3 demonstrates how the schematic circuit diagram embodiment represented by FIG. 1 might actually appear in an MRI scanner.

FIGS. 4 and 5 present alternative embodiments to FIG. 1 that also simultaneously produce a B₀ field and other magnetic field patterns via a shared current configuration.

FIG. 6A shows a structure analogous to FIG. 1 in which a single thin loop is used to form a z-gradient field, and attached current shunts allow the single thin loop to also establish an x-gradient field and y-gradient field. FIGS. 6B and 6C indicate how the acoustic vibration of the structure in FIG. 6A may be reduced.

### DETAILED DESCRIPTION

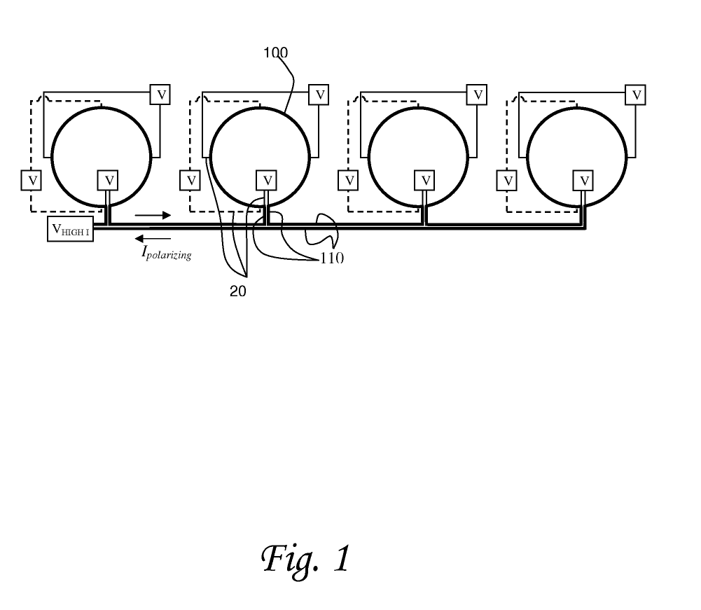

FIG. 1 is a schematic circuit diagram showing a single thick conducting loop 100, represented by a thick black line, that receives power from a single voltage source V_{HIGH I} capable of generating an extremely high current I_{polarizing}. The thick loop 100 has been bent so that several segments 110 of antiparallel current are paired in addition to the antiparallel currents that would normally be expected to be attached to a voltage source V_{HIGH I}. Each such segment pair is understood to have a combined magnetic field approximately equal to zero in the volume of the scanner specified for imaging, which for example may be achieved for a given segment pair through laying the segments very close to each other, telescoping one segment within the other, or intertwining the two segments with each other. Insulation and/or an air gap prevents the segments in a pair from making direct physical contact with each other or directly transmitting electricity to each other. The non-paired segments of 100, which form four circular structures (partial loops), produce a B₀ field with the current I_{polarizing} when the circular structures are appropriately sized and positioned. Three current shunts 20 are attached to each of the four circular structures of 100. Each current receives power from a voltage source V, and activation of the current shunts 20 will redistribute the current in the thick loop 100 such that an x-gradient field, y-gradient field, and/or z-gradient field are added to the B₀ field produced by 100. Shunts are drawn with both solid lines and dashed lines throughout this application to help them to be visually distinguished from each other.

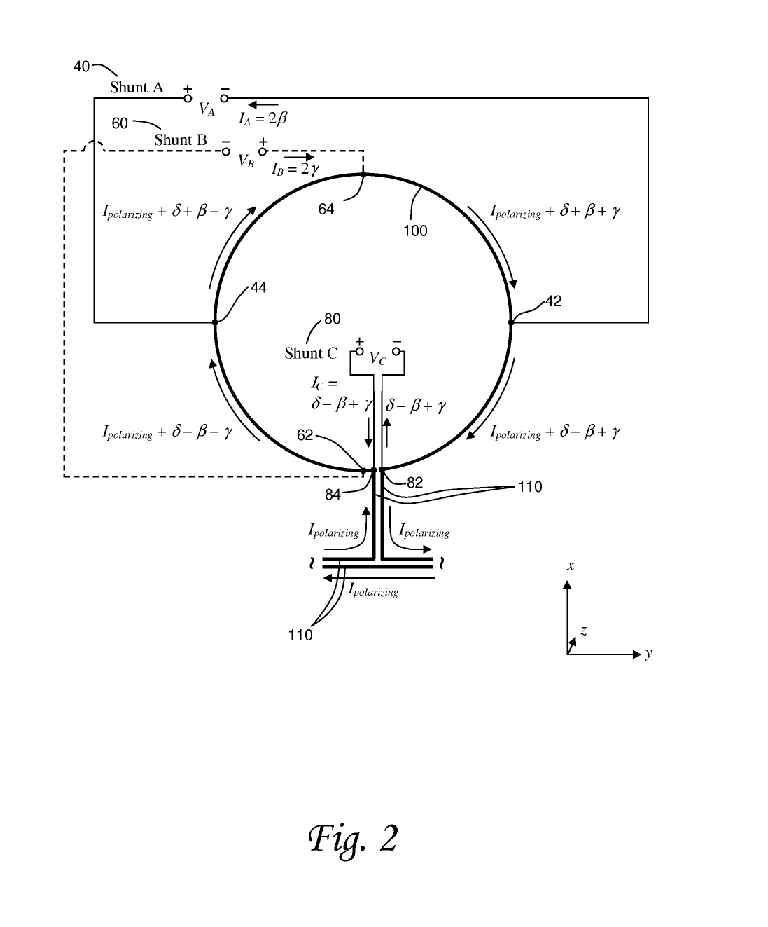

FIG. 2 is a schematic circuit diagram illustrating actual currents that could be associated with any one of the circular structures within the thick loop 100 of FIG. 1. Consistent with the axis shown FIG. 2, the circular structure is understood to be parallel to the x-y plane and centered about the z-axis. Shunt A 40 transmits current from point 42 on the y-axis to point 44 on the y-axis, Shunt B 60 transmits current from point 62 on the x-axis to point 64 on the x-axis, and Shunt C 80 transmits current from point 82 from one segment 110 of the vertical segment pair in FIG. 2 to point 84 on the other segment 110 of the vertical segment pair. Those skilled in the art will recognize that the currents β, γ, and δ produced by the voltage sources would respectively contribute to an x-gradient field, y-gradient field, and/or z-gradient field within the imaging volume of the scanner. Those skilled in the art will further appreciate that Kirchhoff's junction rule and loop rule can be used to readily solve for the magnitudes of the shunt voltages needed for the currents β, γ, and δ shown in FIG. 2. These voltages are:

V_{A}=(2β)R_{A}+2(I_{polarizing}+δ+β)R_{q}

V_{B}=(2γ)R_{B}+2(I_{polarizing}+δ+γ)R_{q}

V_{C}=(δ−β−γ)R_{C}+4(I_{polarizing}+δ)R_{q},

where R_{q} is the resistance of each quarter of the circular structure, R_{A} is the total resistance associated with Shunt A, R_{B} is the total resistance associated with Shunt B, and R_{C} is the total resistance associated with Shunt C.

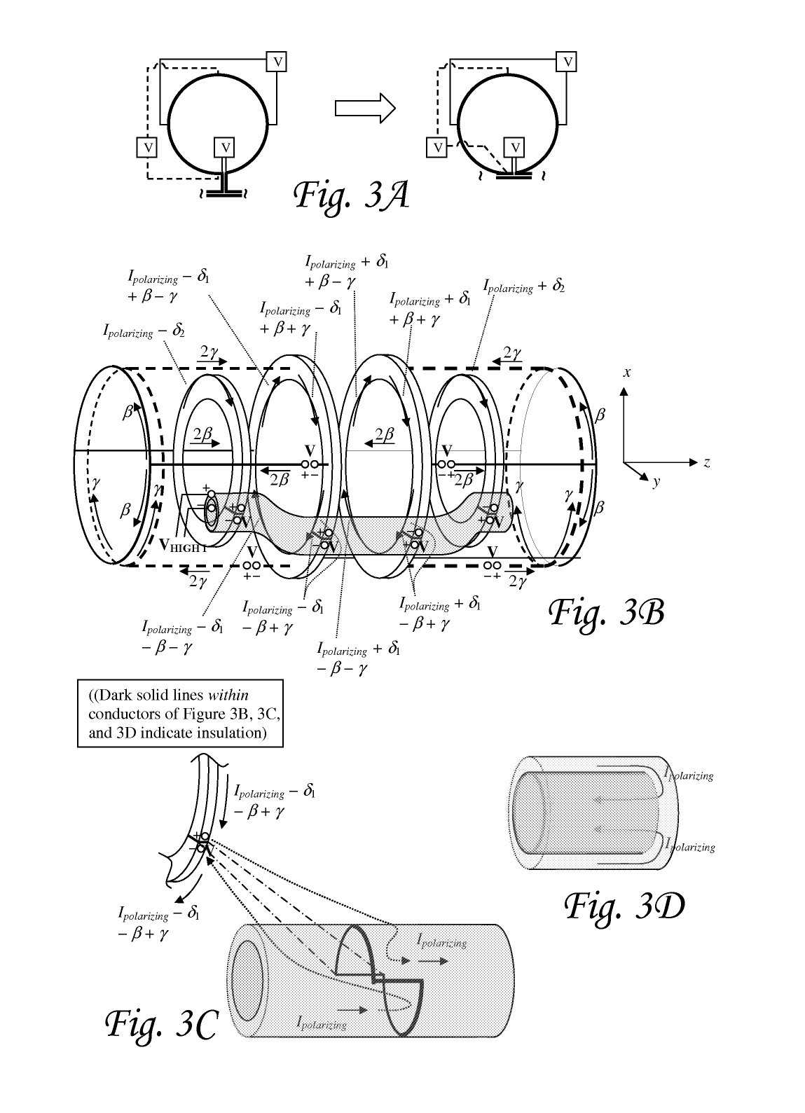

FIG. 3 indicates how the schematic embodiment of FIG. 1 might actually physically appear in an MRI scanner. FIG. 3A is a preparatory figure for FIG. 3B and indicates the vertical segment pairs of FIG. 1 being removed. Although the vertical segment pairs of FIG. 1 help the embodiment to be better understood by more clearly visually separating the segments 110 that are paired from the non-paired segments of 100 that actually produce the B₀ field, they are not necessary for the operation of the embodiment and in fact their currents would be likely to represent a waste of energy. FIG. 3B shows the actual physical manifestation of the schematic circuit of FIG. 1, with each circular structure having the same orientation as the circular structure of FIG. 2. Those of skill in the art will recognize that the opposing δ currents respectively associated with the first two and last two circular structures of the structure is consistent with generation of a z-gradient field, while the parallel β currents of the middle two loops and the parallel γ currents of the middle two loops are consistent with respective generation of an x-gradient field and y-gradient field.

Several practical notes regarding FIG. 3B may be made here. First, each shunt can be seen to split into two branches when traveling perpendicularly to the z-axis. The exact configuration associated with this branching can be shown to preserve the x- and y-gradient magnetic field patterns produced by the scanner. Those of skill in the art could make sure that shunts associated with this disclosure are in general structured so as to not distort the magnetic field pattern desired within the imaging volume of the scanner. Second, the thick loop of FIG. 3B may have to contain slots that prevent the formation of eddy currents within it. These slots should be designed so as to not affect the overall precision of the magnetic field pattern arising from the loop. Third, it can be seen that the voltage sources that drive current in the shunts can be used to overcome the inductance of the thick loop, thus allowing the magnetic field established by the thick loop to be changed as quickly as is typically required for MRI scanning (i.e., in about one half of a millisecond). Fourth, the associated voltage source V_{HIGH I} will likely have to be constructed to specifically handle the extremely high current and extremely low resistance associated with the thick loop. This may be achieved, for example, through the use of a stack of rectifier-controller units wired together in parallel and employing insulated gate bipolar transistors (IGBTs), thyristors, or other semiconductor technologies.

FIG. 3C shows the means by which the circular structures of FIG. 3B are connected together by the tubular structure of FIG. 3B, which collectively corresponds to the horizontal segment pairs of FIG. 1. Clearly, a short countercurrent segment pair will exist between the tubular structure and each circular structure of FIG. 3B, even with the removal of the vertical segment pairs shown via FIG. 3A, just because of the thickness of the conductor from which these structures are built.

FIG. 3D shows the use of telescoping to help ensure that the currents corresponding to the horizontal segment pairs of FIG. 1 do virtually sum to zero within the imaging volume of the scanner. Those of skill in the art would be aware of the ways to achieve the highest degree of current cancellation, and the precision of this current cancellation could be specified in terms of a maximum threshold of corresponding magnetic field contamination allowed within the imaging volume of the scanner (e.g., 1 part per million, 5 ppm, 10 ppm, 50 ppm with respect to the B₀ field magnitude, among other choices).

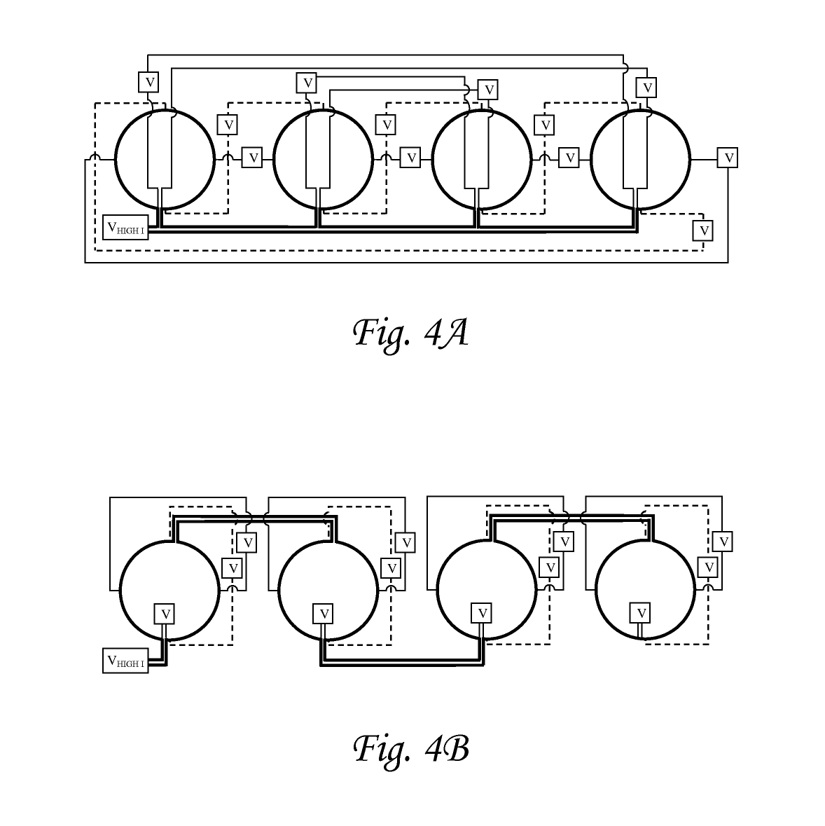

FIG. 4A shows a variation to the embodiment of FIG. 1 in which shunts connect points between different circular structures as opposed to within the same circular structure. FIG. 4B shows a variation to the embodiment of FIG. 1 with which the B₀ field is produced by eight semicircular structures as opposed to four circular structures.

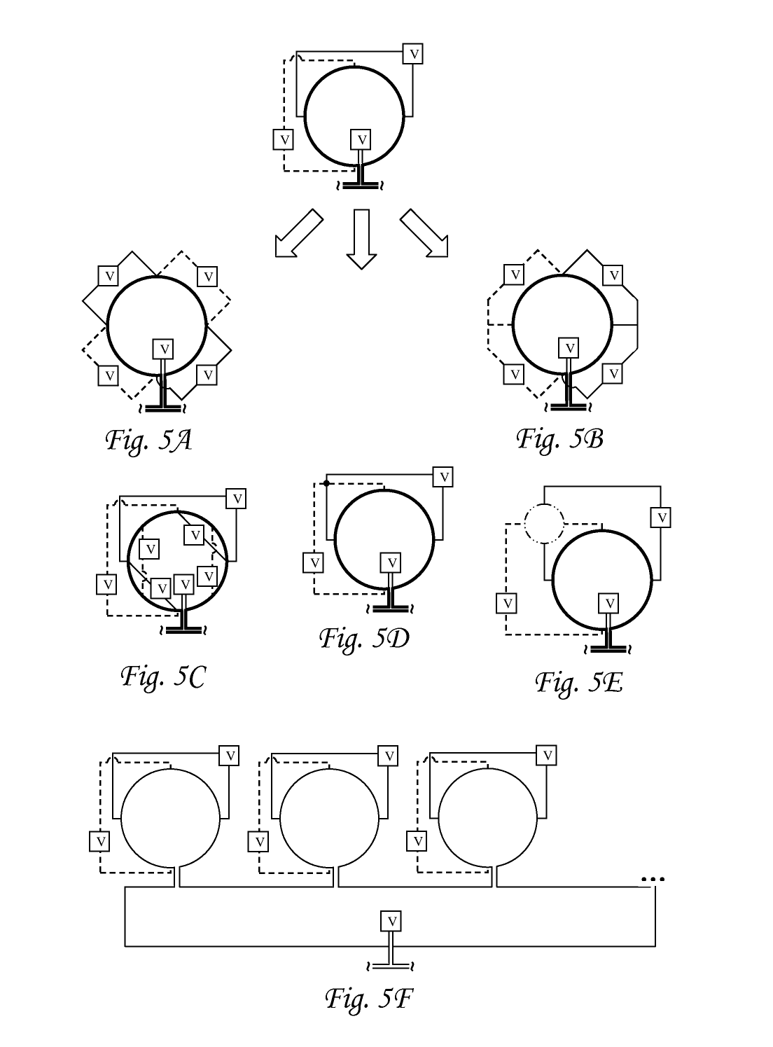

FIG. 5A is a variation to the embodiment of FIG. 1 indicating that two separate shunts can be connected to the same point of the thick loop. FIG. 5B is a variation indicating that a shunt can be connected to more than two points of the thick loop. FIG. 5C is a variation that those of skill in the art will recognize as specifically allowing the thick loop to generate shimming fields in addition to a B₀ field and gradient fields. FIG. 5D indicates that two shunts can intersect at a node and FIG. 5E further suggests that two shunts can intersect via a circle, polygon, or more complex structure.

FIG. 5F is a variation to the embodiment of FIG. 1 that shows a way to achieve a B₀ field and other magnetic field patterns with a summed current structure without actually using either a thick loop or a voltage source capable of generating extremely large currents. Specifically, the thick loop of FIG. 1 is replaced with a thin loop that carries a current only on the order of tens of Amps. Furthermore, instead of the unpaired segments of the loop each forming a rigid circular structure, as in FIG. 1, each unpaired segment is a very long, flexible segment that can be wound in parallel many times. The three thin circular structures at the top of FIG. 5F are supposed to represent individual windings of one such long, flexible segment. The total number of Amp-turns associated with each wound long, flexible segment is large enough for the unpaired segments of FIG. 5F to produce a B₀ field on the order of the B₀ field associated with FIG. 1. Furthermore, the shunts attached to each winding and to the vertical segment pair near the bottom of FIG. 5F permit an x-gradient field, y-gradient field, and/or z-gradient field to be produced simultaneously with that B₀ field.

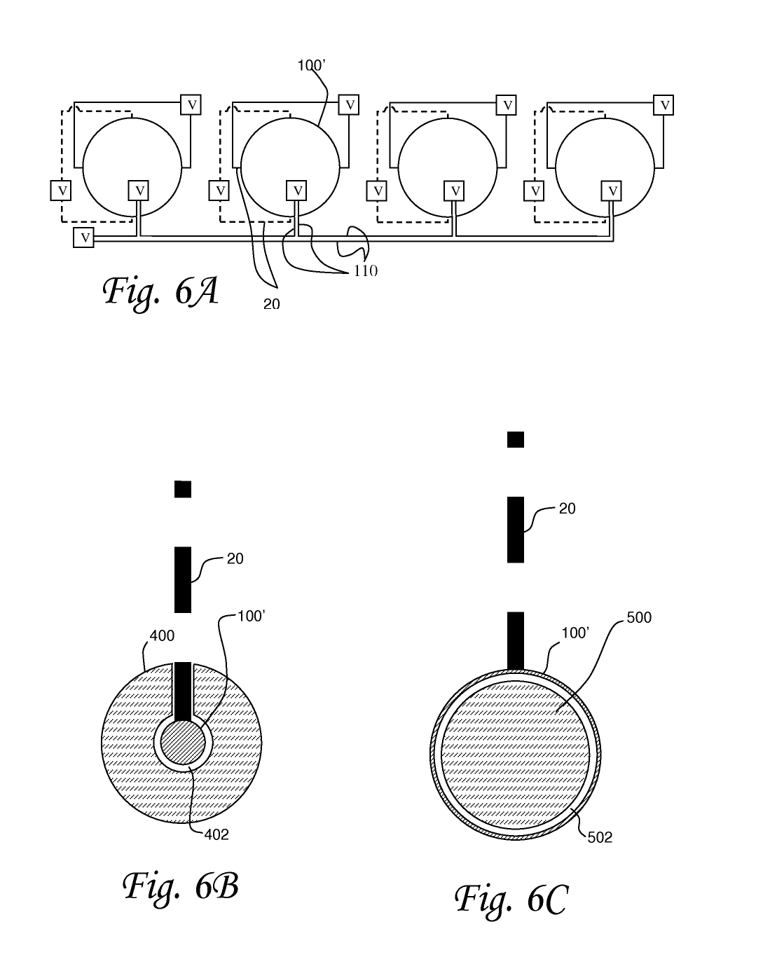

FIG. 6 is a variation to FIG. 1 that, like FIG. 5F, uses a thin loop 100′ that does not carry extremely large currents. The structure of FIG. 6, however, does not contain long flexible segments and windings as that of FIG. 5F does, and so the circuit of FIG. 6 is not meant to produce a B₀ field at all. Instead, FIG. 6 is meant to demonstrate an analog of FIG. 1 in which the main, thin loop establishes a non-B₀ field pattern and the shunts attached to the main, thin loop 100′ are used to add on other magnetic field patterns to that initial non-B₀ field pattern. In the specific case of FIG. 6, the main, thin loop 100′ could produce a z-gradient field and the shunts 20 connected to the loop would then add an x-gradient field and/or a y-gradient field to that z-gradient field.

As is well known to those skilled in the art, a structure exposed to a very strong magnetic field and also containing a current that is changing over time will generally vibrate from Lorentz forces and thereby produce acoustic noise. Segments of the thick loop 100 with changing currents would generally be expected to be immune from Lorentz forces associated with the field emanating from other segments of the thick loop simply because the thick loop will likely weigh on the order of a few thousand kilograms. The thin loop 100′ placed near a B₀ field-producing structure would, on the other hand, clearly be vulnerable to Lorentz forces. One way to mitigate that problem is shown in FIG. 6B. Both the thin loop 100′ and the structure producing the B₀ field have a circular cross section, and part of the thin loop has been symmetrically placed in a hollow circular tunnel 402 that has been symmetrically formed in part of the structure 400 producing the B₀ field. Similarly, in FIG. 6C, both the thin loop 100′ and the structure producing the B₀ field again have a circular cross section, but this time part of the structure 500 producing the B₀ field has been symmetrically placed in a hollow circular tunnel 502 that has been symmetrically formed in part of the thin loop 100′. Those skilled in the art will understand that, due to the symmetry of the configurations depicted in FIG. 6B and FIG. 6C, the acoustic vibration of the part of the thin loop 100′ placed within or made to envelop part of the structure producing the B₀ field will likely be reduced relative to the vibration that that part of 100′ would experience if it were simply left adjacent to the structure producing the B₀ field. Such a reduction in vibration would be expected to be more significant if the part of the thin loop 100′ and the part of the structure producing the B₀ field that are made concentric have a relatively large radius of curvature.

Those skilled in the art will understand that there are many other variations associated with the present disclosure beyond those presented in the above figures. In some embodiments, the thick loop could be made to branch and rejoin, or a plurality of thick loops could be placed together, but the overall structure of currents may still be equivalent to that described for the embodiment of FIG. 1. The thick loop may in some embodiments produce only part of the B₀ field required for the scanner, but otherwise appear as shown in FIG. 1. Each current shunt may in some embodiments possess some variable resistance that could be used in addition to its voltage source to help achieve the required current distribution within the thick loop. Each current shunt may in some embodiments pick up current from multiple points of the thick loop, return current to multiple points of the thick loop, or both. Any given voltage source discussed above may in some embodiments be replaced with a group of voltage sources connected in series and/or in parallel, as for example would likely be the case for the high-current voltage source used to power the loop of the thick-loop scanner. The present disclosure can clearly be used to in systems other than MRI scanners that produce magnetic field patterns. Nuclear Magnetic Resonance Spectroscopy, Electron Paramagnetic Resonance Spectroscopy, and Electron Paramagnetic Resonance Imaging are three examples of non-MRI methods to which the present disclosure can be applied.

### Advantages

Having now disclosed the system and method of the present disclosure, those of ordinary skill in the art will understand that some or all of the advantages described in the following paragraphs may be enabled. In the following paragraphs, the physical embodiment of the circuit drawn in FIG. 1 will be referred to as a “thick-loop scanner”.

A first advantage of a thick-loop scanner can be seen from the fact that, given that the precision of the B₀ field magnetic field pattern is particularly important in MRI, the loops of a thick-loop scanner will likely be designed to have positions, diameters, and thicknesses equal or approximately equal to the positions, diameters, and thicknesses of a typical B₀ field-producing structure in a resistive MRI scanner. This means that, assuming that the paths of the shunts are set to be outside of the volume enclosed by the thick loops as in FIG. 3B, from a spaciousness perspective a thick-loop scanner will be equivalent to an MRI scanner that contains only B₀ field- and B₁ field-producing structures. The size of the radiofrequency coil set may be able to be made larger than is usual due to the space freed up within a thick-loop scanner. The greatly increased sense of spaciousness would be likely to make disease screening more palatable to the general population, and would also increase opportunities for the imaging of obese individuals, the imaging of individuals with claustrophobia, veterinary imaging, and imaging during interventional or surgical procedures.

A second advantageous feature of a thick-loop scanner is the relatively low manufacturing cost expected. Only one significant magnetic field-producing structure other than the B₁ field-producing structure would have to be manufactured for the scanner. Furthermore, the thick loop would presumably be assembled from molded pieces and consequently be more cost-effective to make in comparison to structures formed from the careful, repeated winding of wires. Molded structures may also be less susceptible to errors arising from the mechanical stresses of transport than wound structures are, and for that reason it might be more economical to disassemble a thick-loop scanner and reassemble it elsewhere, for example, for donation to a developing nation, than would be the case for a scanner with a large number of windings. It is true that current shunts will have to be manufactured along with the thick loop of a thick-loop scanner, and attached to that thick loop; however, like the thick loop itself, the current shunts are relatively simple structures.

A third advantageous feature of a thick-loop scanner is its capability to provide relatively quiet operation. In standard MRI, the different structures are often placed within one another in the form of tightly-fitting concentric cylinders; however, as, explained above, the thick-loop scanner will be expected to have a relatively large amount of free space. Part of this increased space could be devoted to the placement of slender evacuated tubes around the current shunts, which would significantly reduce the noise transmission resulting from Lorentz forces acting on the shunts when their currents change in value. If the shunts happen to have the arrangement depicted in FIG. 3B, then the evacuated tubes used to enclose the shunts could simply consist of eight straight evacuated tubes and two circular evacuated rings. Evacuated tubes would not have be placed around any part of the thick loop itself as it will probably weigh on the order of 1000 kg and would therefore be unlikely to significantly vibrate as its currents change.

Having now read and understood the disclosed system and method for the simultaneous establishment of a B₀ field and other magnetic field patterns, those of ordinary skill in the art will recognize other advantages, variations, and embodiments that have been enabled by the foregoing disclosure. Such advantages, variations, and embodiments shall be considered to be part of the scope and meaning of the appended claims and their legal equivalents.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of this disclosure.

The scope of the present disclosure includes any feature or combination of features disclosed herein (either explicitly or implicitly), or any generalization thereof, whether or not it mitigates any or all of the problems addressed herein. Various advantages of the present disclosure have been described herein, but embodiments covered by the claims may provide some, all, or none of such advantages.

What is claimed is:

1. A magnetic resonance imaging (MRI) device, comprising:
a conductor operable to carry a current between first and second terminals of a loop voltage source, wherein the conductor comprises:
a plurality of loop portions disposed about a central axis, wherein the plurality of loop portions includes a first loop portion coupled to the first terminal of the loop voltage source and a second loop portion coupled to the second terminal of the loop voltage source by a return portion of the conductor;
one or more inter-loop portions connecting the plurality of loop portions in series;
a first plurality of current shunts coupled between first and second nodes of respective ones of the plurality of loop portions, wherein each of the first plurality of current shunts includes a single voltage source;
a second plurality of current shunts coupled between third and fourth nodes of respective ones of the plurality of loop portions, wherein each of the second plurality of current shunts includes a single voltage source;
a third plurality of current shunts coupled between two nodes respectively on two interloop portions connected to ones of the plurality of loop portions, wherein each of the third plurality of current shunts includes a single voltage source;
wherein a magnetic field of the MRI device is generated substantially by the plurality of loop portions of the conductor.

2. The apparatus of claim 1, wherein the conductor carries a polarizing magnetic field current of at least 10,000 amps.

3. The apparatus of claim 1, wherein the selected respective currents are operable to create at least one gradient magnetic field.

4. The apparatus of claim 1, wherein the selected respective currents are operable to create at least two gradient magnetic fields.

5. The apparatus of claim 1, wherein the selected respective currents are operable to create at least three gradient magnetic fields.

6. The apparatus of claim 1, wherein the selected respective currents are operable to create at least one shimming magnetic field.

7. The apparatus of claim 1, wherein any net contaminating magnetic field arising from the inter-loop and return portions of the conductor has a magnitude of less than 1 part per million with respect to the polarizing magnetic field within the imaging volume of the scanner.

8. The apparatus of claim 1, wherein any net contaminating magnetic field arising from the inter-loop and return portions of the conductor has a magnitude of less than 5 parts per million with respect to the polarizing magnetic field within the imaging volume of the scanner.

9. The apparatus of claim 1, wherein any net contaminating magnetic field arising from the inter-loop and return portions of the conductor has a magnitude of less than 50 parts per million with respect to the polarizing magnetic field within the imaging volume of the scanner.

10. The apparatus of claim 1, wherein any net contaminating magnetic field arising from the inter-loop and return portions of the conductor has a magnitude of less than 100 parts per million with respect to the polarizing magnetic field within the imaging volume of the scanner.
